(19) United States
(12) Patent Application Publication
(10) Pub. No.: US 2013/0185617 A1
(43) Pub. Date: Jul. 18, 2013

(54) WIRELESS BACKHAUL COMMUNICATION

(71) Applicant: Texas Instruments Incorporated, Dallas, TX (US)

(72) Inventors: June Chul ROH, Allen, TX (US); Srinath HOSUR, Plano, TX (US); Pierre BERTRAND, Antibes (FR); Anand DABAK, Plano, TX (US)

(73) Assignee: TEXAS INSTRUMENTS INCORPORATED, Dallas, TX (US)

(21) Appl. No.: 13/740,729

(22) Filed: Jan. 14, 2013

Related U.S. Application Data
(60) Provisional application No. 61/585,958, filed on Jan. 12, 2012.

(51) Int. Cl. H04W 4/00; H03M 13/09

(52) U.S. Cl. CPC H04W 4/00; H03M 13/09
USPC 714/800; 370/328

(57) ABSTRACT

A method for wireless backhaul communication comprising receiving, by a wireless backhaul transmitter, a data stream in a bit format and generating, by the wireless backhaul transmitter using a single-carrier block transmission scheme, a radio frame to include a plurality of physical data channel (PDCH) blocks, a pilot signal (PS) block and a physical control channel (PCCH) block with each block type pre-appended with a cyclic prefix (CP). A length of the PS block in symbols, a length of the PCCH block in symbols and a length of the PDCH block in symbols is determined by a frequency band, a bandwidth, and a channel condition. The wireless backhaul transmitter then transmits the radio frame.

### CROSS-REFERENCE TO RELATED APPLICATION

The present application claims priority to U.S. Provisional Patent Application No. 61/585,958, filed on Jan. 12, 2011 (Attorney Docket No. TI-71913PS); which is hereby incorporated herein by reference.

### BACKGROUND

Many wireless backhaul systems are based on single-carrier, time-domain equalization (SC-TDE) techniques but have limited configurability and require line-of-sight (LOS) communication pathways. Since wireless backhaul systems often operate in the 6-42 GHz microwave frequency band they may require to operate in line-of-sight, point-to-point channels. Due to the LOS requirement and the use of SC-TDE, such wireless backhaul systems have limited throughput and flexibility.

### SUMMARY

The problems noted above are solved in large part by a method for wireless backhaul communication comprising receiving, by a wireless backhaul transmitter, a data stream in a bit format and generating, by the wireless backhaul transmitter using a single-carrier block transmission scheme, a radio frame to include a plurality of physical data channel (PDCH) blocks, a pilot signal (PS) block and a physical control channel (PCCH) block with each block type pre-appended with a cyclic prefix (CP). A length of the PS block in symbols, a length of the PCCH block in symbols and a length of the PDCH block in symbols is determined by a frequency band, a bandwidth, and a channel condition. The wireless backhaul transmitter then transmits the radio frame.

Other embodiments are directed toward a wireless backhaul system, comprising a wireless transceiver to receive a data stream in bit format, a transmitter chain to convert the data stream into a digital radio frame, wherein the digital radio frame includes N physical data channel (PDCH) blocks with each PDCH block comprising a cyclic prefix (CP) pre-appended to a corresponding PDCH block and the transmitter chain uses a single-carrier block transmission scheme. A radio frequency (RF) front end to convert the digital radio frame into a first analog signal and transmit the first analog signal.

Another embodiment is directed toward a wireless backhaul transmitter, comprising a transmitter to produce and transmit a radio frame. The transmitter comprising a frame formatter to receive data in bits and to arrange the bits into data blocks of bits, a forward error-checking (FEC) encoder to receive the data blocks of bits from the frame formatter, to encode the data blocks and to generate FEC blocks of bits for each data block of bits. The transmitter chain also comprising a scrambler to receive the FEC blocks from the spreader and to scramble the bits within each FEC block of the radio frame, a symbol mapper to receive the FEC blocks from the scrambler and to map the bits of the FEC blocks to symbols to form N PDCH blocks. The transmitter chain also comprising a cyclic prefix (CP) adder to receive the radio frame from the symbol mapper and to pre-append each of the N PDCH blocks with a CP, a pilot signal (PS) and physical control channel (PCCH) multiplexer to receive the N PDCH blocks from the CP adder and to combine at least one PS block and a PCCH block with the N PDCH blocks to form a radio frame. The transmitter chain also comprising a pulse shaping filter to receive the radio frame from the PS and PCCH multiplexer and to shape the pulses that comprise the radio frame, an interpolator and re-sampler to receive the radio frame from the pulse shaping filter and to convert the sample rate of the radio frame to a rate more favorable for a digital-to-analog convertor (DAC) component of an analog RF front-end. The transmitter chain also comprising the analog RF front-end to receive the radio frame from the interpolator and re-sampler, to convert the radio frame to an analog signal and to transmit the analog signal.

### BRIEF DESCRIPTION OF THE DRAWINGS

For a detailed description of various examples, reference will now be made to the accompanying drawings in which:

FIG. 1 shows an embodiment of a wireless backhaul system in accordance with the principles disclosed herein;

FIG. 2 shows an embodiment of a radio frame 100 in accordance with the principles disclosed herein;

FIG. 3a shows an embodiment of a block pre-appended with a cyclic prefix (CP) block in accordance with the principles disclosed herein;

FIG. 3b shows an embodiment of a block pre-appended with a unique word (UW) block in accordance with the principles disclosed herein;

FIG. 4 shows a block diagram of a transmitter chain and a receiver chain based on single-carrier frequency domain equalization (SC-FDE) used in a wireless backhaul system in accordance with the principles disclosed herein;

FIG. 5 shows a block diagram of a transmitter chain and a receiver chain based on SC-FDE used in a wireless backhaul system with XPIC capability (for dual polarization techniques) or MIMO capability in accordance with the principles disclosed herein;

FIG. 6a is a chart showing wireless backhaul system parameters for a wireless backhaul system operating in the sub-6 GHz spectrum in accordance with the principles disclosed herein;

FIG. 6b is a chart showing alternative wireless backhaul system parameters for a wireless backhaul system operating in the sub-6 GHz spectrum in accordance with the principles disclosed herein;

FIG. 6c is a chart showing wireless backhaul system parameters for a wireless backhaul system operating in the 6-42 GHz microwave spectrum in accordance with the principles disclosed herein;

FIG. 6d is a chart showing wireless backhaul system parameters for a wireless backhaul system operating in the 60-80 GHz spectrum in accordance with the principles disclosed herein; and

FIG. 7 shows an embodiment of a method for generating and transmitting the radio frame 200 in accordance with the principles disclosed herein.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical or wireless connection. Thus, if a first device couples to a second device, that connection may be through a direct electrical or wireless connection, or through an indirect electrical or wireless connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Next generation wireless backhaul systems, on the other hand, require increased throughput and re-configurability, along with non-LOS (NLOS) or near LOS, in addition to LOS communication. The next generation system may also require increased bandwidth, the ability to support multiple data streams through multiple-input, multiple-output (MIMO) techniques, and co-channel dual polarization transmission techniques. Unfortunately, conventional wireless backhaul systems may be stretched to meet such new demands.

To satisfy the new requirements, a single-carrier, frequency domain equalization (SC-FDE) method may be implemented for block-based transmission, or single-carrier block transmission, of payload along with other operation and management data for the wireless backhaul system. Due to the complexity of FDE being lower than TDE for high-throughput systems, with SC-FDE it may be easier to implement advanced techniques for providing high spectral efficiency such as cross-polarization interference cancellation (XPIC) and multiple-in, multiple-out (MIMO) techniques.

SC-FDE may also display a good combination of the advantages of single-carrier and multi-carrier systems, but with the lower-complexity equalization of multi-carrier systems. SC-FDE may be characterized by low peak-to-average-power ratio (PAPR) as conventional SC-TDE does, which may allow the use of less costly power amplifiers at the transmitter. Low PAPR may also allow for a smaller back-off requirement at the transmitter, which may allow for a larger transmission range. Moreover, SC-FDE operates robustly in NLOS channels as well as LOS channels by configuring appropriate system parameters.

Disclosed herein are a method and systems to generate and transmit radio frames over a wireless backhaul system using a SC-FDE scheme. Each radio frame may comprise a physical control channel (PCCH) block, a number of pilot signal (PS) blocks, and a plurality of physical data channel (PDCH) blocks. The PDCH block may contain the data, or payload, of the wireless backhaul system. Each type of block may be pre-appended with a cyclic prefix (CP) making each block N_{CP}+N_{FFT} symbols in length. The length of each block may be set at system start-up. However, the number of symbols used per block, N_{FFT}, may be configurable and may be altered due to the use of a different frequency band, bandwidth, and channel condition. The wireless backhaul system may utilize a transmitter chain that generates the radio frame from a data stream received in bit format.

The transmitter chain may begin by formatting the bits of the data stream into a radio frame comprising of a number of blocks of bits before encoding the data using a forward error-checking (FEC) encoder. After encoding, spreading, and scrambling, the bits in each block may be mapped to symbols. After mapping, the data may be encoded blocks of symbols where each block contains the data. After symbol mapping, a CP may be pre-appended to each block. After the addition of the CP to each block, the transmitter chain may insert at least one PS block and a PCCH block into the radio frame. The PS block and the PCCH block may be in symbol format. After the addition of the PS block and the PCCH block, the radio frame structure is obtained. Alternatively, the PCCH block may be omitted from the radio frame structure. Now, the radio frame goes through a pulse shaper, an interpolator and re-sampler, and a digital pre-distorter before being converted to an analog signal and wirelessly transmitted by a microwave antenna.

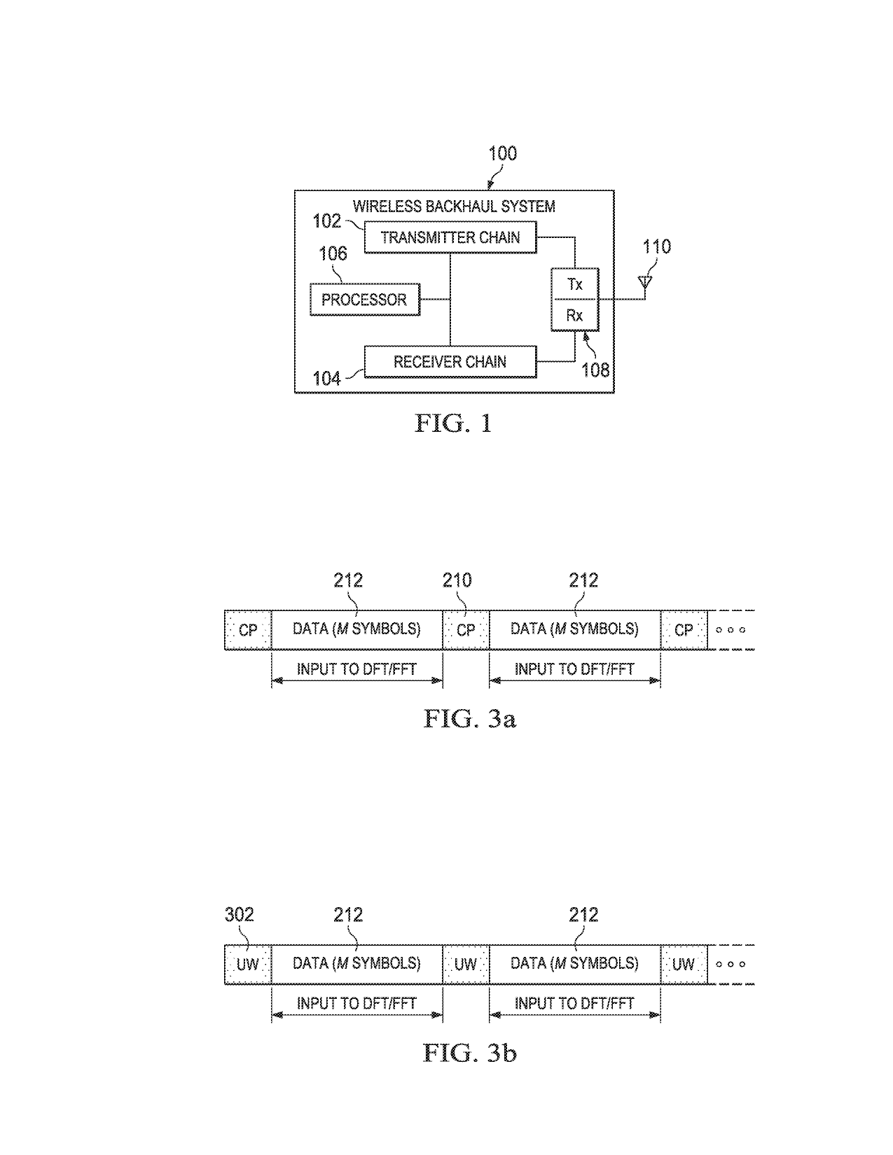

FIG. 1 is an embodiment of a wireless backhaul system 100. The wireless backhaul system 100 may comprise a transmitter chain 102, a receiver chain 104, a processor 106, a duplexer 108, and a microwave antenna 110. The wireless backhaul system may receive backhaul information data as an input, which may be a data stream received by the transmitter chain 102. The transmitter chain 102 may transform the bit data into a radio frame for transmission. The transmitter chain 102 may be denoted as the PDCH. Further, the transmitter chain 102 may also receive a PS and control data via a PCCH to be added as blocks to the radio frame structure. Further, the wireless backhaul system 100 may implement a SC-FDE scheme when generating and transmitting the radio frame.

The PCCH may go through a similar transmitter chain but the transmitter chain used to generate the PCCH may use a different modulation and FEC scheme. For example, a lower modulation order (e.g., BPSK or QPSK) and a simple and low-latency FEC (not necessarily the same FEC used for the PDCH), and possibly with a spreading and transmit diversity scheme.

The wireless backhaul system 100 may be used by a wireless communication system to send and receive signals along wireless connections between cellphone tower base stations, between base station to other backhaul nodes, and between backhaul nodes. Additionally, the wireless backhaul system 100 may be implemented in hardware or using software in combination with a processor, such as processor 106, or through a combination of hardware and software. For example, the transmitter chain 102 may contain functional blocks for mapping bits to symbols or encoding that may be implemented in hardware while other functional blocks, such as applying spreading functionality, may be implemented by a processor.

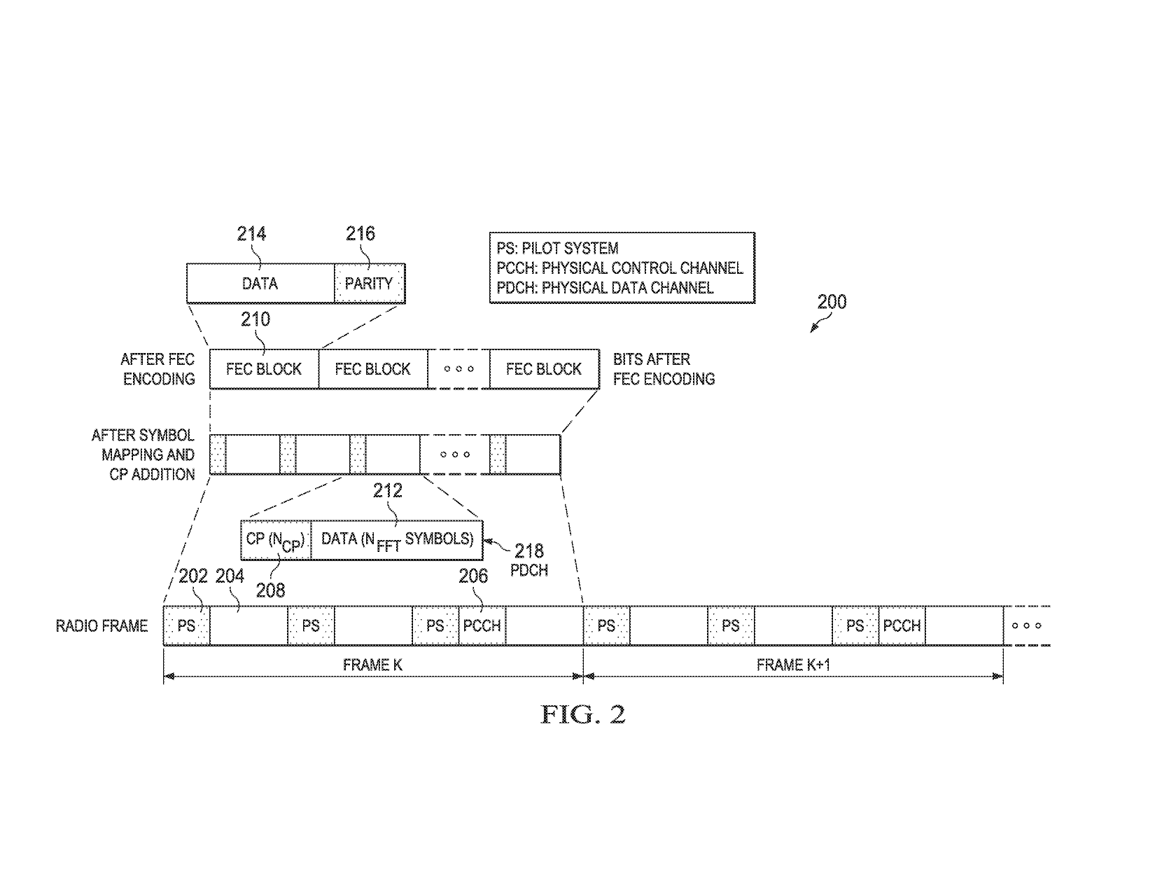

FIG. 2 shows multiple radio frames 200 (frames K and K+1). Each frame of the radio frame 200 may comprise a PS block 202, N physical data channel (PDCH) blocks 204 and a PCCH block 206. Each radio frame 200 may be used to transmit payloads between nodes of a wireless backhaul system. Alternatively or additionally, each radio frame 200 may contain N PDCH blocks 201, multiple PS blocks 202, and no PCCH block 206. Further, the radio frame 200 may contain one PS block 202 for each of the N PDCH blocks 204 and one PCCH block 206. The radio frame 200 may include operation and management information regarding the transmission parameters of the wireless backhaul system. For ease of description, the subsequent discussion will be in reference to only one frame of the radio frame 200, for example, frame K as shown in FIG. 2.

The PS block 202 may be pre-appended with a CP and may be N_{CP}+N_{FFT} symbols in length. The PS block 202 may be used at the receiver for signal detection, symbol timing recovery, carrier frequency recovery and channel estimation and tracking. The PS block 202 may be transmitted at the beginning of each radio frame 200. Placing the PS block 202 symbols at the beginning of each radio frame 200 may done when the wireless backhaul system is operating in a packet transmission mode. Otherwise, when the wireless backhaul system is operating in a continuous transmission mode, more than one PS block 202 may be placed periodically throughout the radio frame 200. For example, if N equals 100, meaning there are 100 PDCH blocks 204, then there may be a PS block 202 every 25 PDCH blocks.

The PCCH block 206 may be pre-appended with a CP and may be N_{CP}+N_{FFT} symbols in length. The PCCH block 206 may be used to carry operation and management related information, including adaptively changing modulation order and/or the code rate based on the channel condition. The PCCH symbols may also be protected with a different forward error correction (FEC) method, code rate, and by using a different modulation type that the PDCH block 218. Alternatively or additionally, the PCCH block 206 may be transmitted in a time-division multiplexed manner. Further, the PCCH block 206's length in symbols may be less than the PS block 202 and the PDCH block 204 due to the number of bits required to transmit the operation and management related information. Alternatively or additionally, the length in symbols of the PCCH block 206 may be N_{FFT}/2ⁿ, where n=0, 1, 2, 3, etc.

Each of the blocks 204 may comprise of multiple PDCH blocks 218. Each PDCH block 218 may be the symbol mapped version of an FEC block 210 pre-appended with a CP 208. Based on a modulation order and an FFT length, the FEC blocks 210 may be mapped to a single data block 212 or multiple data blocks 212. Stated another way, a data block 212 may contain less than all the symbols of a symbol mapped FEC block 210 or a data block 212 may contain the symbols of multiple FEC blocks 210. Each PDCH block 218 may be N_{CP}+M symbols in length. Alternatively, each data block 212 may be pre-appended with a unique word (UW) and may also have a length of N_{CP}+M symbols. Thus, each PDCH block 218 may be a data block pre-appended with a CP 208 or a UW 302.

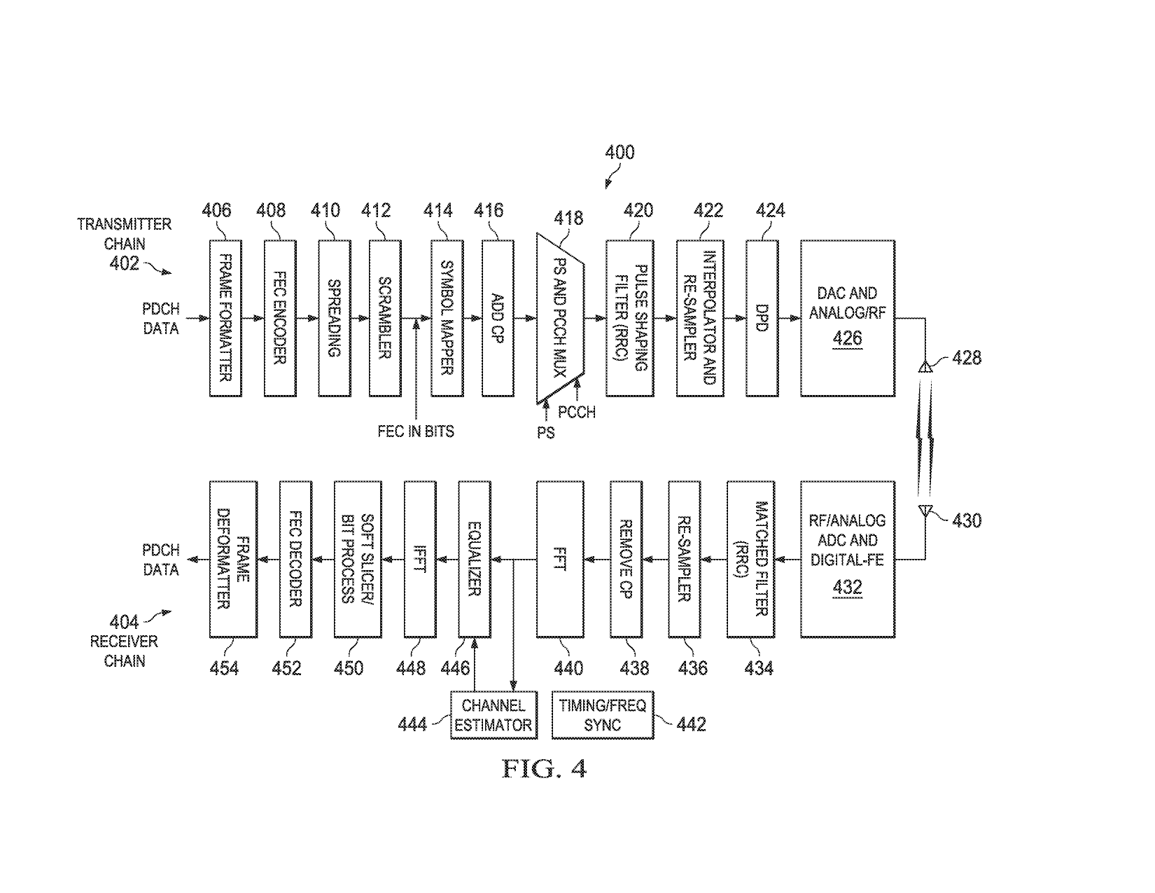

FIG. 3a shows an embodiment of a data block 212 pre-appended with a CP 208. The PS blocks 202 and the PCCH block 206 may also be formed in the same manner. The block shown is M symbols in length and the combination of the data block and the CP 208 may be referred to as an extended block. The CP 208 may be a copy of the last N_{CP} symbols of the block to which it is pre-appended. Pre-appending a block with a corresponding CP 208 may result in an extended block of N_{CP}+M symbols in length. In accordance with various embodiments, M may represent N_{FFT} symbols. The CP length (N_{CP}) is configurable depending on channel environment, system bandwidth, and frequency band, but may not be adjusted once it is set up, for example at system setup. Conventionally, N_{CP} may be set equal to or larger than an actual channel delay spread of the wireless channel. By making the CP 208 length configurable, the wireless backhaul system may work robustly in various radio channel conditions, and LOS, near LOS, and NLOS conditions. Additionally or alternatively, when using the radio frame 200 in the implementation of a dual-polarization signal, the CP 208 may assist with recovering/decoding slightly time misaligned data streams when using a XPIC-LOS backhaul system.

FIG. 3b shows an embodiment of a block pre-appended with a UW 302 to form an alternative extended block. As with the CP 208, the UW 302 may be pre-appended to the data blocks 212, and may be a part of the PS block 202 and the PCCH block 206. The UW 302 may be a predetermined training sequence of length N_{CP} symbols. Also like the CP 208, the UW 302 may be configurable and may be set equal to or larger than an actual channel delay spread of a wireless channel, which may produce a radio frame 100 that is robust in various radio channel conditions. Lastly, the FEC block 210 may be 4096 or 8192 bits in length and may comprise a data block 214 and a parity block 216.

The difference between using a CP 208 and a UW 302 in the radio frame 200 may be outlined in reference to decoding the signal on the receiver side, such as by receiver chain 404. When using the CP 208 in the radio frame 200, the CP 208 may be removed from the received extended block, so that only the data is decoded, which may be the N_{FFT} symbols to be decoded. Alternatively, if the CP 208 is replaced with a UW 302, then the UW 302 is not removed from the data block 212 before decoding. The UW 302 may be part of the N_{FFT} symbols needed for decoding.

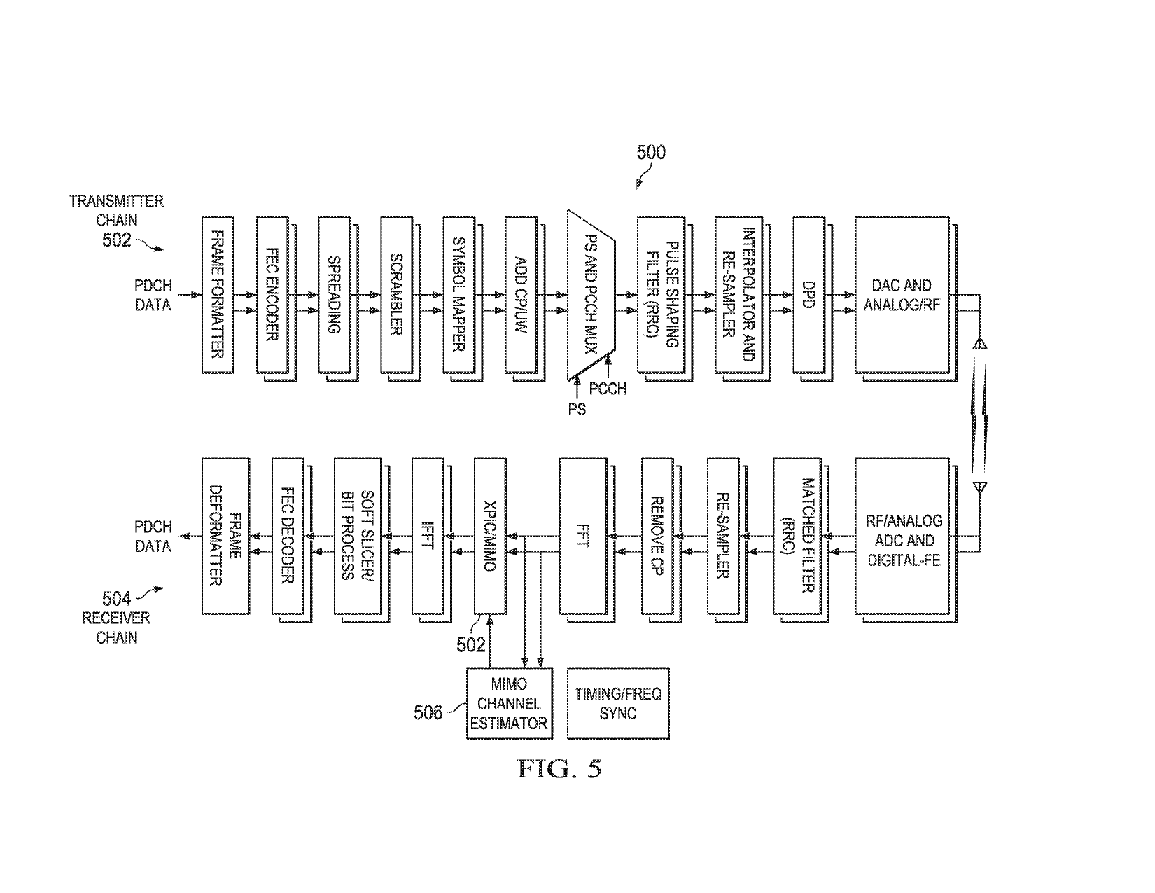

FIG. 4 shows an embodiment of a transmitter chain and a receiver chain 400 used in a wireless backhaul system, or wireless backhaul transceiver. The embodiment shown is just one way to implement the transmission of the radio frame 200 and other ways to produce the same transmission are possible as well. The transmitter chain 402 may be used as a wireless backhaul system transmitter front-end to produce and transmit radio frames, or packets, similar to the radio frame 200 format utilizing a single-carrier signal with frequency-domain equalization. The receiver chain 404 may be used as a wireless backhaul system front-end to receive and decode packets similar to the radio frame 200.

The transmitter chain 402 may receive backhaul information data from host logic (not shown) of the wireless backhaul system, such as the wireless backhaul system 100, or the payload, to be transmitted. The backhaul information data may be received in bit format and may be transformed into block format for transmission. The radio frame to be transmitted, such as radio frame 200, may be generated by components of the transmitter chain 402. The transmitter chain 402 may comprise of two sections, a bit-level section and a symbol-level section. The bit-level section may comprise a frame formatter 406, a FEC encoder 408, a spreader 410, and a scrambler 412. The symbol-level section of the transmitter chain 402 may comprise the remainder of the chain. The input to the transmitter chain 402 may be initially received by the frame formatter 406. The frame formatter 406 may receive the data in bit format and form it into a number of blocks of a number of bits in length, e.g., k bits in length, depending on a modulation order, code rate, and a fast Fourier transform (FFT) block length. The frame formatter 406 may also arrange the data into an order based on priority.

The forward error correction (FEC) encoder 408 may receive the output from the frame formatter 406. The FEC encoder 308 may process a block of k bits in which the FEC encoder 408 calculates and concatenates (n-k) bits of parity bits to form an encoded block of length n bits, similar to an FEC block 210. For example, a low density parity check (LDPC) code may be used as an FEC code. The output of the FEC encoder 408 may flow into a spreader 410. The spreader 410 may add redundancy to the data based on a spreading factor. For example, a spreading factor of 2 may result in a doubling of each bit of the data so that an FEC block 212 of 4096 bits would become 8192 bits. The spreader 410 may be optional in the transmitter chain 402 and may be absent from some embodiments. The output of the spreading 410 may flow into a scrambler 412. The scrambler 412 scrambles the encoded bit stream and may be implemented as either a self-synchronization (multiplicative) scrambler or as a side-stream (additive) scrambler. Alternatively, the FEC encoder 408, the spreading 410, and the scrambler 412 may be combined into one component of the transmitter chain 402 or the spreading factor component 410, and the scrambler 412 may be combined into one component.

A symbol mapper 414 may receive the output from the scrambler 412. The symbol mapper 414 may map the scrambled bits to symbols depending on the modulation type, e.g. BPSK, QPSK, or QAM. The symbol mapper 414 may then form the symbols into blocks of length M, similar to data block 212, which is a configurable parameter that can be optimized for system requirements. After the bits are mapped into symbols and formed into blocks, the CP, similar to CP 208, is pre-appended to the PDCH blocks using an add CP 416 component. Alternatively, the add CP 416 component may be replaced with an add UW component so that a UW block, similar to UW 302, is pre-appended to the data blocks in place of the CP block. The output of the CP add 416 may be similar to PDCH blocks 206.

A pilot signal (PS) and physical control channel (PCCH) multiplexer (PS and PCCH mux) 418 component then receives the mapped blocks with the pre-appended CP (or UW) block, such as PDCH blocks 206. The PS and PCCH mux 418 may combine the PS block 202 and the PCCH block 206 with the N PDCH blocks 206 and may comprise a radio frame format similar to the radio frame 200. As discussed above, the PS block 202 may be inserted at the head of each radio frame if the wireless backhaul system is operating in packet transmission mode. Alternatively, the PS blocks 202 may be inserted every integer number of PDCH blocks. After PS block and PCCH block insertion, a pulse shaping filter (RRC) 420 component receives the radio frame. The RRC 420 may use a root-raised cosine filter to shape the pulses that comprise the radio frame 200.

An interpolator and re-sampler 422 may then receive the radio frame, or data stream, from the RRC 420. The interpolator and re-sampler 422 may convert the sample rate of the data stream to a rate that is more favorable for the remaining components of the transmitter chain—a digital pre-disposition (DPD) 424 component and a digital-to-analog convertor (DAC). The DPD 424 may receive the output of the interpolator and re-sampler 422 and may compensate non-linearity of power amplifiers so the transmitter chain 402 has better overall performance. Before being transmitted by a microwave antenna 428, the data stream is received by a DAC and Analog/RF convertor 426, which is used to convert the analog signal to an analog signal before mixing it with an RF signal, which is then sent to the microwave antenna 428. Alternatively, the DAC and Analog/RF convertor 426 may receive the data stream directly from the interpolator and re-sampler 422 by bypassing or omitting the DPD 424 component from the transmitter chain 402.

Referring again to FIG. 4, the receiver chain 404 of a wireless backhaul system for SC-FDE may be implementation dependent. The received signal samples (after analog/RF and data conversion block) may be filtered with a matched filter (e.g., RRC filter) and resampled at a baseband sampling rate. The matched filtering may be implemented either in time-domain (via FIR filter) or frequency-domain (after taking DFT, which also may be merged with channel equalization).

The receiver chain 404 begins by receiving the signal by a microwave antenna 430. The signal is then transmitted to a RF/analog analog-to-digital convertor (ADC) and digital front-end 432. A matched filter 434 receives the radio frame 200 from the RF/analog analog-to-digital convertor (ADC) and digital front-end 432. The matched filter 434 is used to filter the signal out from any noise in the signal. The matched filter 434's output is received by a resampler 436, which converts the sample rate from the ADC to a rate more compatible with the rest of the receiver chain 404. After the resampler 436, the radio frame 200 is received by a remove CP 438 component. The remove CP 438 removes the CP block 210 from each extended block 208 leaving only the PDCH blocks 204 of length N_{FFT}, which are then ready for FFT. FIG. 3a shows the portion of the extended block 208 that will be fed into FFT. Alternatively, if a UW block 302 is used in place of the CP block 210, the UW blocks are not removed and, instead, a block of samples are taken for FFT processing and equalization processing with the UW block 302 intact, as is shown in FIG. 3b. The FFT windowing is performed by a FFT 440 component, which receives the PDCH blocks 204 of length N_{FFT} from the remove CP 438.

Feed-forward equalization may be collectively performed on PDCH blocks 204 of length N_{FFT} by the FFT 440, the equalization 446 and the IFFT 448. Samples corresponding to a PDCH blocks 204 of length N_{FFT} are transformed into frequency domain by the FFT 440 and the feed-forward equalization is performed in the frequency domain. The equalized frequency-domain samples are transformed back to time-domain by IFFT 448 component. Before the samples are processed by IFFT 448 they are received by a channel estimator 444 and equalizer 446 components. Lastly, the samples are processed by soft slicer/bit process 450 and then FEC decoder 452 before being de-framed by frame de-formatter 454. The output of the receiver chain 404 is the PDCH data in bits.

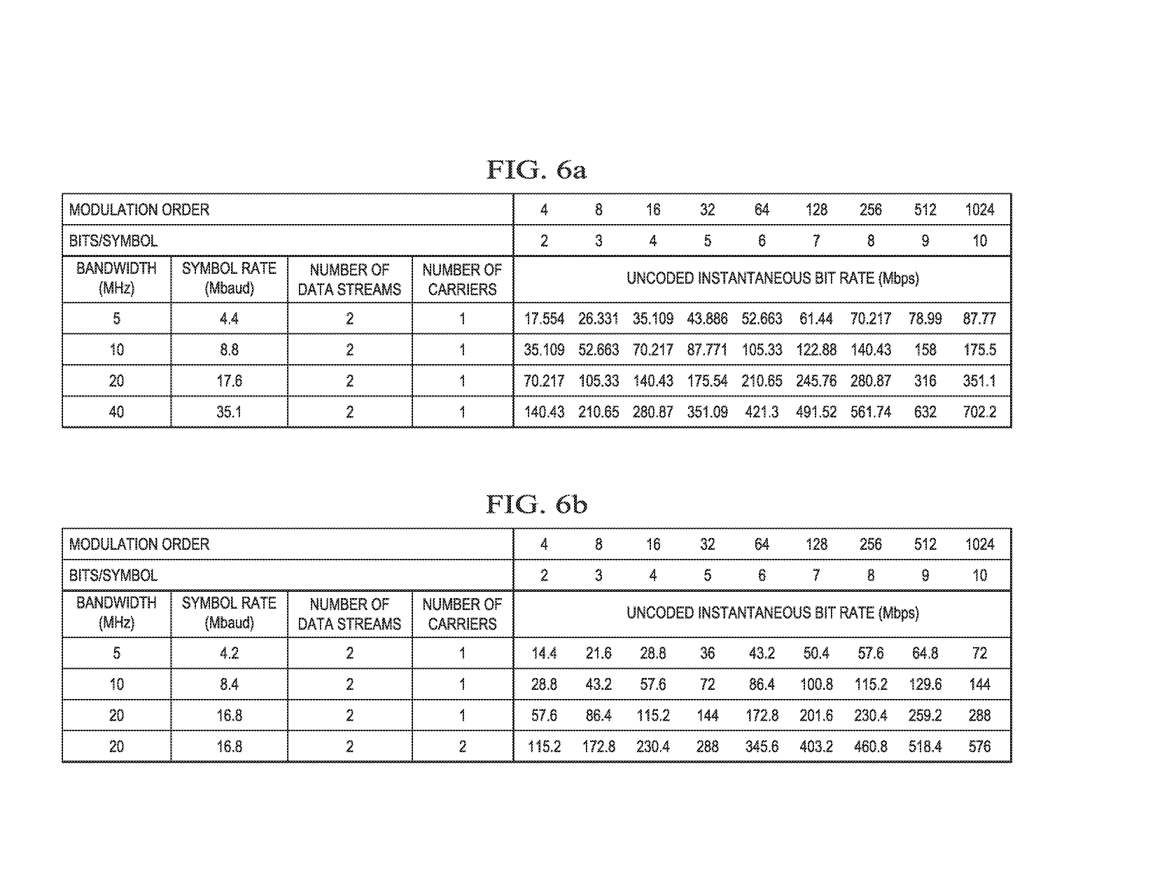

FIG. 5 shows an embodiment of a wireless backhaul system 500 based on SC-FDE that supports dual-polarization transmission or multiple-input multiple-output (MIMO) for high spectral-efficiency systems. For dual-polarization transmission, both the vertical and the horizontal polarizations may be used to transmit information between nodes of the wireless backhaul system 500. The transmission of a dual-polarization signal may only require one microwave antenna, such as microwave antenna 428. To implement MIMO transmission, the wireless backhaul system 500 may use two microwave antennas at both the transmitter and receiver.

The wireless backhaul system 500 may comprise two data paths in the transmitter chain 502 and two data paths in the receiver chain 504. The components, or modules, comprising the two data paths of both the transmitter chain 502 and the receiver chain 504 may be identical to the components comprising the transmitter chain 402 and the receiver chain 404 except for the addition of the MIMO estimation and cross-polarization interference cancelation or equalization functionality of the XPIC/MIMO 502.

The MIMO channel estimator 504 may estimate complex channel gain matrix, for example, a 2×2 matrix for XPIC and a 2×2 matrix for MIMO, for each sub-carrier, or polarization, of the received signal. The estimated channel information may be used in XPIC/MIMO equalization. The XPIC/MIMO 502 equalization may implement minimum mean square error (MMSE) or zero-forcing equalization method. The wireless backhaul system 500 implementing two data streams may also be extended to support more data streams, for example, four data streams. Expanding to more data streams may be achieved by implementing both 2×2 MIMO and XPIC in the same frequency band. In such an embodiment, the XPIC/MIMO estimation may estimate a 4×4 complex channel gain for each sub-carrier, which may be used in XPIC/MIMO 502.

In accordance with various embodiments, a configurable wireless backhaul system may have the capability of XPIC and MIMO to support 2 data streams and may be configured to support two different wireless data links. For example, as in a relay node that has two links. In accordance with various other implementations, the wireless backhaul system 500 may use four data paths identical to the transmission chain 402 to produce the two different wireless data links. The use of four data paths may allow the wireless backhaul system 500 to support transmitting two SC-FDE signals both supporting dual-polarization transmission. Alternatively, a four transmission chain wireless backhaul system 500 may support 4 signal MIMO transmission using a single carrier frequency or 2 carrier frequencies with each carrier frequency supporting a 2×2 MIMO transmission.

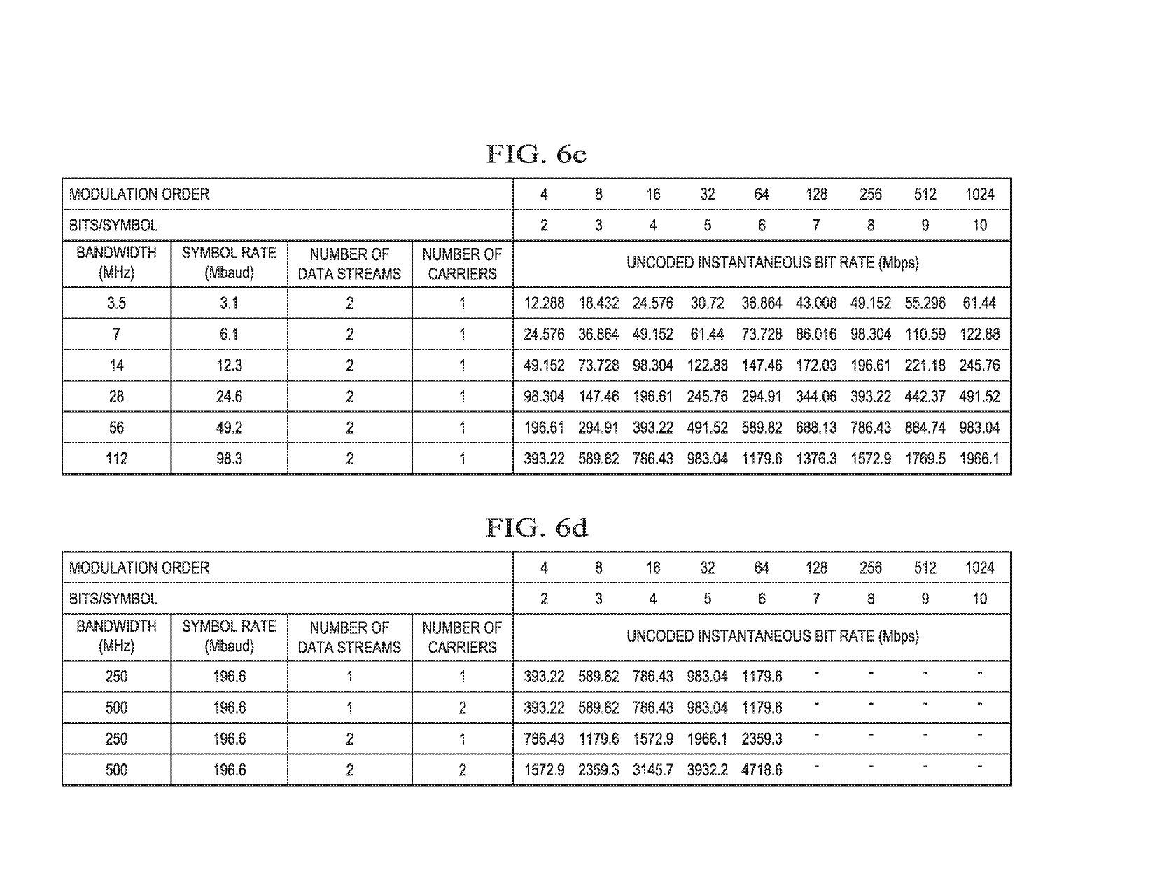

FIG. 6a is an illustrative chart of the system parameters for a wireless backhaul system using SC-FDE in the sub 6 GHz bands. For each bandwidth (BW) shown, there are two associated design parameters—a corresponding symbol rate, a number of data streams—for the SC-FDE scheme. For a given BW, a symbol rate and a roll-off factor may need to be decided upon to determine an uncoded bit rate of a wireless backhaul system. A roll-off factor associated with the pulse shaping filter 420 may be used to calculate the symbol rate associated with the chosen BW. For example, choosing a BW of 10 MHz and using a roll-off factor of 14% may result in a symbol rate of 8.8 Mbaud.

Additionally, the wireless backhaul system may implement adaptive coding and modulation (ACM). ACM may allow the radio frame's coding modulation and/or modulation order to be changed depending on channel conditions due to, for example, weather conditions. Such that, when the weather is poor, a lower modulation order may be chosen. The Modulation order may determine a number of bits to use per symbol by symbol mapper 414. For example, on a rainy data, a modulation order of 4 may be chosen, which may use 2 bits per symbol (QPSK) and on a sunny day, 10 bits per symbol (1024-QAM) may be chosen.

FIG. 6b is an illustrative chart showing alternative wireless backhaul system parameters for a wireless backhaul system operating in the sub-6 GHz bands. The information in FIG. 6b may be used substantially similar to how the information in FIG. 6a is used but supporting different symbol rates. The bottom row of FIG. 6b shows the system parameters when using two carriers, which may require four data streams, and is one example of carrier aggregation for single polarization transmission. Four data streams may require four transmitter chains similar to the transmitter chain 402.

FIG. 6c is an illustrative chart of the system parameters for a wireless backhaul system using SC-FDE in the 6-42 GHz microwave bands. The information in FIG. 6b may be used substantially similar to how the information in FIG. 6a is used.

FIG. 6d is an illustrative chart of the system parameters for a wireless backhaul system using SC-FDE in the 60-80 GHz microwave bands. The information in FIG. 6c may be used substantially similar to how the information in FIG. 6a is used.

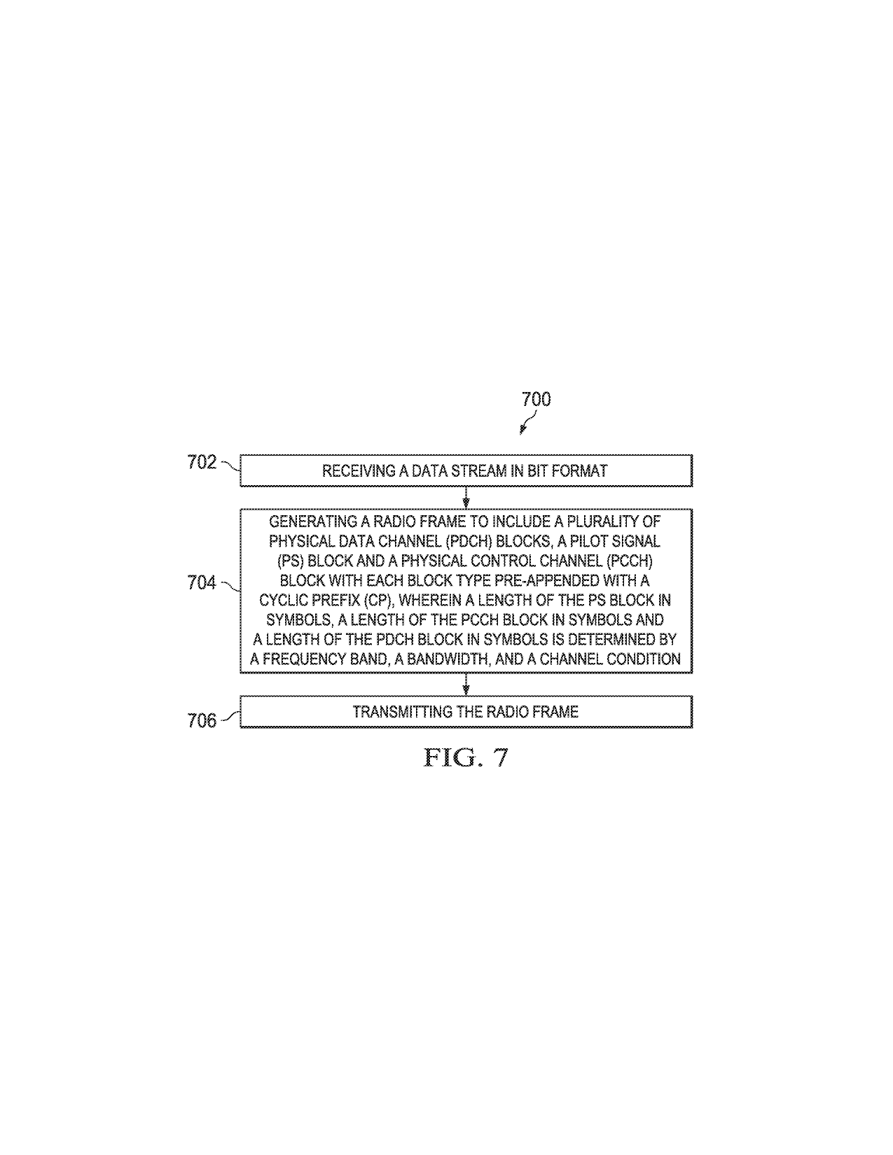

FIG. 7 shows an embodiment of a method for generating and transmitting the radio frame 200. Method 700 begins at block 702 with receiving a data stream in bit format. Similar to the backhaul information data received by the transmitter chain 402. Method 700 continues at block 704 with generating a radio frame to include a number of physical data channel (PDCH) blocks that include a cyclic prefix (CP), a pilot signal (PS) block and a physical control channel (PCCH) block, wherein a length of the PS block in symbols, a length of the PCCH block in symbols and a length of the PDCH block in symbols is determined by a frequency band, a bandwidth, and a channel condition. The generation method is similar to the functional components used by the transmitter chain 402 and the radio frame may be similar to the radio frame 200. Method 700 ends with transmitting the radio frame. The transmission of the radio frame is similar to the transmission performed by the transmission chain 402.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method for wireless backhaul communication, comprising:
receiving, by a wireless backhaul transmitter, a data stream in a bit format;
generating, by the wireless backhaul transmitter using a single-carrier block transmission scheme, a radio frame to include a plurality of physical data channel (PDCH) blocks, a pilot signal (PS) block and a physical control channel (PCCH) block with each block type pre-appended with a cyclic prefix (CP), wherein a length of the PS block in symbols, a length of the PCCH block in symbols and a length of the PDCH block in symbols is determined by a frequency band, a bandwidth, and a channel condition; and
transmitting the radio frame.

2. The method of claim 1, wherein the CP is a copy of the last N_{CP} symbols of the corresponding block type to which the CP is pre-appended.

3. The method of claim 1, wherein the length of the PCCH block in symbols is N_{CP}+N_{FFT}/2ⁿ symbols in length, where n is any positive integer greater than or equal to zero.

4. The method of claim 1, wherein the CP is replaced with a unique word of a known sequence.

5. A wireless backhaul system, comprising:
a wireless transceiver to receive a data stream in bit format;
a transmitter chain to convert the data stream into a digital radio frame, wherein the digital radio frame includes N physical data channel (PDCH) blocks with each PDCH block comprising a cyclic prefix (CP) pre-appended to a corresponding PDCH block, wherein the transmitter chain uses a single-carrier block transmission scheme; and
a radio frequency (RF) front end to convert the digital radio frame into a first analog signal and transmit the first analog signal.

6. The system of claim 4, wherein the CP is a copy of the last N_{CP} symbols of the corresponding PDCH block, where each PDCH block is N_{FFT} symbols in length.

7. The system of claim 4, wherein the digital radio frame further includes a pilot signal (PS) block pre-appended with a CP so that the PS block is N_{CP}+N_{FFT} symbols in length and a physical control channel (PCCH) block pre-appended with a CP so that the PCCH block is N_{CP}+N_{FFT} symbols in length.

8. The system of claim 4, wherein the number of symbols used for each block is determined by a frequency band, a bandwidth, and a channel condition.

9. The system of claim 4, wherein the length of the PCCH block in symbols is N_{CP}+N_{FFT}/2ⁿ symbols in length, where n is any positive integer greater than or equal to zero.

10. The system of claim 4, further comprising a wireless receiver to receive a second analog signal from another wireless backhaul system, to convert the second analog signal into a digital signal using al using a single-carrier block transmission scheme, and process the digital signal in order to extract a data stream from the digital signal.

11. The transmitter chain of claim 4, comprising:
a frame formatter to receive the data in bits and to format the bits into blocks of bits;
an forward error-checking (FEC) encoder to receive the radio frame from the frame formatter, to encode the radio frame to include the parity information, and to generate FEC blocks of bits;
a scrambler to receive the FEC blocks from the FEC encoder and to scramble the bits within each FEC block of the radio frame;
a symbol mapper to receive the scrambled FEC blocks from the scrambler and to map the bits of the scrambled FEC blocks to symbols forming the N PDCH blocks;
a CP block adder to receive the N PDCH blocks from the symbol mapper and to pre-append each PDCH block with a CP block thereby producing an extended PDCH block for each PDCH block;
a pilot signal and PCCH multiplexer to receive the N extended PDCH blocks from the CP block adder and to insert at least one PS block and a PCCH block into the radio frame, wherein the at least one PS block and the PCCH block are in symbol format and the combination of the extended PDCH blocks, the PCCH block and the at least one PS block form the radio frame;
a pulse shaping filter to receive the radio frame from the pilot block and PCCH multiplexer and to shape the pulses that comprise the radio frame; and
an interpolator and re-sampler to receive the radio frame from the pulse shaping filter and to convert the sample rate of the radio frame to a rate more favorable for a digital-to-analog convertor (DAC) component of an analog RF front-end.

12. The system of claim 4, wherein the wireless transceiver includes two transmitter chains with each transmitter chain generating a separate radio frame to be transmitted on a different polarization of the first analog signal.

13. The system of claim 4, wherein the wireless transceiver includes two transmitter chains with each transmitter chain generating a separate radio frame to be transmitted by a separate microwave antenna.

14. The system of claim 4, wherein the wireless transceiver includes four transmitter chains generating a separate radio frame.

15. The system of claim 4, wherein each transmitter chain uses the same PCCH.

16. The system of claim 4, wherein each transmitter chain uses a separate PCCH.

17. The system of claim 4, wherein each transmitter chain uses the same encoding method, code rate, and modulation order.

18. The system of claim 4, wherein each transmitter chain uses a different encoding method, code rate, and modulation order.

19. A wireless backhaul transmitter, comprising:
a transmitter to produce and transmit a radio frame, the transmitter comprising:
a frame formatter to receive data in bits and to arrange the bits into data blocks of bits;
a forward error-checking (FEC) encoder to receive the data blocks of bits from the frame formatter, to encode the data blocks and to generate FEC blocks of bits for each data block of bits;
a scrambler to receive the FEC blocks from the spreader and to scramble the bits within each FEC block of the radio frame;
a symbol mapper to receive the FEC blocks from the scrambler and to map the bits of the FEC blocks to symbols to form N PDCH blocks;
a cyclic prefix (CP) adder to receive the radio frame from the symbol mapper and to pre-append each of the N PDCH blocks with a CP;
a pilot signal (PS) and physical control channel (PCCH) multiplexer to receive the N PDCH blocks from the CP adder and to combine at least one PS block and a PCCH block with the N PDCH blocks to form a radio frame;
a pulse shaping filter to receive the radio frame from the PS and PCCH multiplexer and to shape the pulses that comprise the radio frame;
an interpolator and re-sampler to receive the radio frame from the pulse shaping filter and to convert the sample rate of the radio frame to a rate more favorable for a digital-to-analog convertor (DAC) component of an analog RF front-end; and
the analog RF front-end to receive the radio frame from the interpolator and re-sampler, to convert the radio frame to an analog signal and to transmit the analog signal.

20. The transmitter of claim 16, wherein the CP block is a copy of the last N_{CP} symbols of the corresponding PDCH block and the PDCH block is N_{FFT} symbols in length.

21. The transmitter of claim 16, wherein the PS block is pre-appended with the CP so that the PS block is N_{CP}+N_{FFT} symbols in length and is used for signal recovery by a receiver.

22. The transmitter of claim 16, wherein the PCCH block is pre-appended with the CP so that the PCCH block is N_{CP}+N_{FFT} symbols in length and is used to relay operation and management information for a wireless backhaul system.

23. The transmitter of claim 16, wherein the number of symbols used by the pilot block, the PCCH block and the body frame is determined by a frequency band, a bandwidth, and a channel condition.

24. The transmitter of claim 16, wherein the PCCH block is N_{CP}+N_{FFT}/2ⁿ symbols in length, where n is any positive integer greater than or equal to zero.
